(19) United States
(12) Patent Application Publication
(10) Pub. No.: US 2008/0096393 A1
(43) Pub. Date: Apr. 24, 2008

(54) Apparatus and method of etching a semiconductor substrate

(75) Inventors: In-Gi Kim, Yongin-si (KR); Dae-Hyuk Chung, Seongnam-si (KR); Dae-Hyuk Kang, Hwaseong-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/907,081

(22) Filed: Oct. 9, 2007

(30) Foreign Application Priority Data
Oct. 18, 2006 (KR) 10-2006-101159

(51) Int. Cl. H01L 21/461

(52) U.S. Cl. 438/745; 156/345.11; 257/E21.483

(57) ABSTRACT

An apparatus for etching a semiconductor substrate may include a bath, a reaction preventing layer, and a nozzle. The bath may receive a chemical solution. Grooves may be formed at the inner wall of the bath. The reaction preventing layer may be formed on the inner wall and in the grooves of the bath to reduce or prevent a chemical reaction between the chemical solution and the bath. The nozzle may supply the chemical solution to the bath. In a method of etching a semiconductor substrate, the semiconductor substrate having trench structures and an insulation layer pattern may be prepared. The semiconductor substrate may then be dipped into the bath having the reaction preventing layer in which the chemical solution is received. The semiconductor substrate may be reacted with the chemical solution by blocking the chemical reaction between the chemical solution and the bath to etch the insulation layer pattern and the trench structure at a uniform rate.

### PRIORITY STATEMENT

This application claims priority under 35 USC §119 to Korean Patent Application No. 2006-101159, filed on Oct. 18, 2006, in the Korean Intellectual Property Office (KIPO), the entire contents of which are herein incorporated by reference.

### BACKGROUND

1. Field

Example embodiments relate to an apparatus and a method of wet-etching a semiconductor substrate using a chemical.

2. Description of Related Art

In a process for forming a semiconductor device, a silicon nitride layer may be uniformly etched at a temperature of about 165° C. using a phosphoric acid (H₃PO₄) solution as an etching solution. When a wet etching process using a phosphoric acid solution is performed, a silicon oxide layer as well as the silicon nitride layer may be uniformly etched. The phosphoric acid solution may have a uniform etching selectivity within the range of the etching selectivity of the silicon nitride layer and the silicon oxide layer. For example, the etching selectivity of the phosphoric acid solution with respect to the etching selectivity of the silicon nitride layer and the silicon oxide layer may play an important role in improving the profile of the trench structure of a trench during a shallow trench isolation (STI) process.

However, when the etching process using a phosphoric acid solution is repeatedly performed, the etched thickness of the silicon oxide layer may be gradually reduced although the etched thickness of the silicon nitride layer may be constantly maintained. Thus, the etching selectivity of the silicon nitride layer and the silicon oxide layer with respect to the phosphoric acid solution may be gradually increased. As such, a phosphoric acid solution may be reacted with a bath having quartz in which the phosphoric acid solution is received as well as the silicon oxide layer such that the etched thickness of the silicon oxide layer may be reduced.

Therefore, as the etching selectivity of the silicon nitride layer and the silicon oxide layer with respect to the phosphoric acid solution is gradually increased, the trench structure in the STI process may have a less desirable profile. Particularly, the insulation layer including silicon nitride between the trench structures may be etched. In contrast, the trench structure including silicon oxide may not be etched. Thus, as illustrated in FIG. 1, the profile of the trench structure may have a negative slope. As a result, when a polysilicon layer is formed between the trench structures, a void may be formed in the polysilicon layer.

To improve the profile of the trench structure as illustrated in FIG. 2, the etching process using a phosphoric acid solution may be carried out in a multi-step process. Further, to constantly maintain the etched thickness of the silicon oxide layer by the phosphoric acid solution, the phosphoric acid solution may be frequently replaced with a new solution. However, because the etching process may be carried out in a multi-step process, it may take longer to complete the etching process. Further, the cost in performing the etching process may be increased due to the frequent replacement of the phosphoric acid solution.

### SUMMARY

Example embodiments provide an apparatus for etching a semiconductor substrate that may be capable of constantly maintaining an etching selectivity between the etching selectivity of a silicon nitride layer and a silicon oxide layer with respect to a phosphoric acid solution. Example embodiments also provide a method of etching a semiconductor substrate using the above-mentioned apparatus.

An apparatus for etching a semiconductor substrate in accordance with example embodiments may include a bath and a reaction preventing layer. The bath may receive a chemical solution for etching the semiconductor substrate. Further, a plurality of grooves may be formed at the inner wall of the bath. The reaction preventing layer may be formed on the inner wall and in the grooves of the bath to reduce or prevent the occurrence of a chemical reaction between the chemical solution and the bath.

The bath may include quartz and the reaction preventing layer may include Teflon. Each of the grooves may have an inlet diameter and a bottom diameter longer than the inlet diameter. A nozzle for supplying the chemical solution to the bath may be further arranged at the bottom face of the bath. Further, the nozzle may include quartz for reducing or preventing an occurrence of a chemical reaction between the chemical solution and the nozzle.

In a method of etching a semiconductor substrate in accordance with example embodiments, the semiconductor substrate having trench structures and an insulation layer pattern may be prepared. The trench structures may be formed in trenches of the semiconductor substrate. The insulation layer pattern may be formed between the trench structures. The semiconductor substrate may then be dipped into a bath in which a chemical solution may be received. A reaction preventing layer for reducing or preventing an occurrence of a chemical reaction between the chemical solution and the bath may be formed on the inner wall of the bath. The semiconductor substrate may be reacted with the chemical solution by blocking the chemical reaction between the chemical solution and the bath so as to etch the insulation layer pattern and the trench structure at a uniform rate.

The chemical solution may include a phosphoric acid solution. The phosphoric acid solution may be at a temperature of about 160° C. to about 170° C.

The trench structures may include silicon oxide and the insulation layer pattern may include silicon nitride.

The reaction preventing layer may reduce or prevent an occurrence of a chemical reaction between the phosphoric acid solution and the quartz in the bath such that the etching selectivity of the silicon nitride layer and the silicon oxide layer with respect to the phosphoric acid solution may be constantly maintained.

### BRIEF DESCRIPTION OF THE DRAWINGS

Example embodiments will be more clearly understood from the following detailed description taken in conjunction with the accompanying drawings. FIGS. 1-10 represent non-limiting, example embodiments as described herein.

FIGS. 1 and 2 are photographs illustrating semiconductor substrates etched using a conventional apparatus;

FIG. 3 is a cross-sectional view illustrating an apparatus for etching a semiconductor substrate in accordance with example embodiments;

FIG. 4 is an enlarged cross-sectional view illustrating the portion “A” of FIG. 3;

FIG. 5 is a flow chart illustrating a method of etching a semiconductor substrate in accordance with example embodiments;

FIGS. 6 and 7 are cross-sectional views illustrating the method of FIG. 5;

FIG. 8 is a graph illustrating etching rates of a phosphoric acid solution with respect to a silicon nitride layer and a silicon oxide layer as a function of the lapse of time when an etching process is performed on a semiconductor substrate;

FIG. 9 is a graph illustrating etching rates of a phosphoric acid solution with respect to a silicon nitride layer and a silicon oxide layer as a function of the lapse of time when an etching process is not performed on a semiconductor substrate; and

FIG. 10 is a graph illustrating the etching rate of a phosphoric acid solution with respect to a silicon oxide layer as a function of the lapse of time.

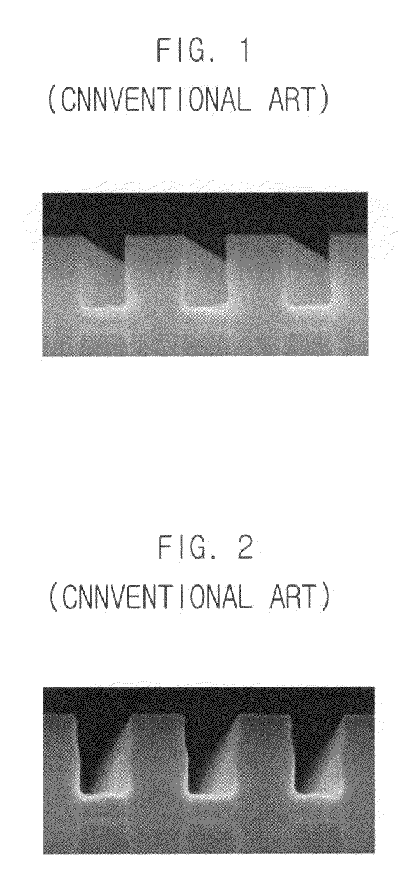

### DETAILED DESCRIPTION OF EXAMPLE EMBODIMENTS

Reference will now be made in detail to example embodiments, examples of which are illustrated in the accompanying drawings. However, example embodiments are not limited to the embodiments illustrated hereinafter, and the embodiments herein are rather introduced to provide easy and complete understanding of the scope and spirit of example embodiments. In the drawings, the thicknesses of layers and regions are exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

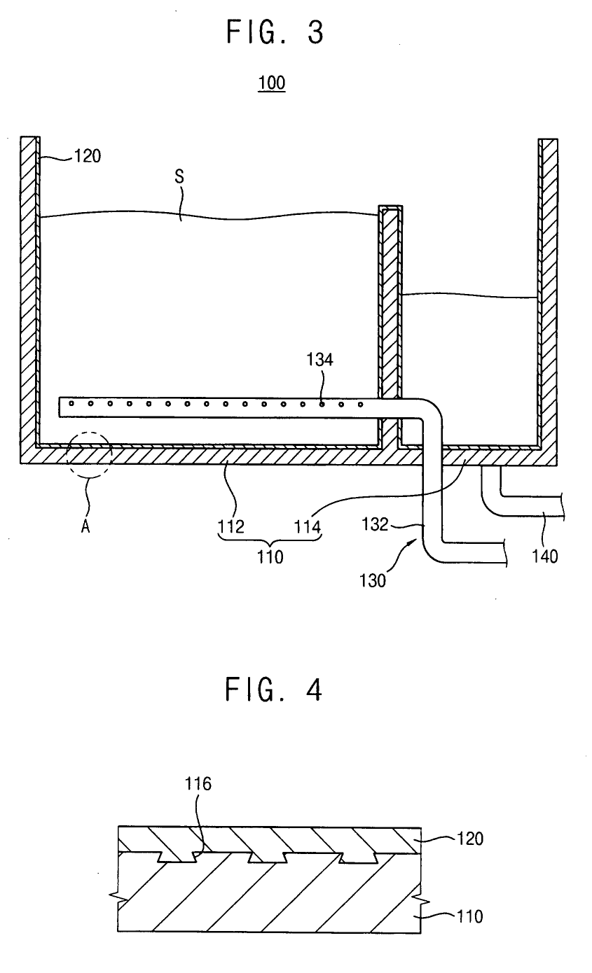

FIG. 3 is a cross-sectional view illustrating an apparatus for etching a semiconductor substrate in accordance with example embodiments. FIG. 4 is an enlarged cross-sectional view illustrating the portion “A” of FIG. 3.

Referring to FIGS. 3 and 4, an apparatus 100 for etching a semiconductor substrate may include a bath 110 for receiving a chemical solution (e.g. a phosphoric acid solution S), a reaction preventing layer 120 formed on the inner wall of the bath 110, a supply member 130 for supplying the phosphoric acid solution S to the bath 110, and an exhaust member 140 for exhausting the phosphoric acid solution S from the bath 110.

The bath 110 may include a main chamber 112 and an auxiliary chamber 114. The main chamber 112 may receive a plurality of the semiconductor substrates (not shown). The semiconductor substrates may be arranged such that there is a uniform interval between the substrates along a horizontal direction of the main chamber 112. Further, the semiconductor substrates may be supported by wafer guides (not shown). The main chamber 112 may receive the phosphoric acid solution S for etching the semiconductor substrates. The auxiliary chamber 114 may be arranged adjacent to the main chamber 112 to receive the portion of the phosphoric acid solution S that has overflowed from the main chamber 112.

Because the phosphoric acid solution S in the bath 110 may be maintained at a temperature of about 160° C. to about 170° C., the bath 110 may include a high temperature-resistant material. Further, because the phosphoric acid solution S having a higher temperature may cause a radical temperature variation in the bath 110, the bath 110 may include a temperature variation-resistant material. Because a phosphoric vapor may be generated from the phosphoric acid solution S having a higher temperature, the bath 110 may include a material that is more stable with respect to the phosphoric vapor. In example embodiments, the bath 110 may include quartz.

As illustrated in FIG. 4, a plurality of grooves 116 may be formed at the inner wall of the bath 110. The grooves 116 may be formed by a wet etching process. Particularly, a Teflon layer may be formed on the inner wall of the bath 110 to partially expose the inner wall of the bath 110 through the Teflon layer. A potassium hydroxide (KOH) solution may be poured into the bath 110. The KOH solution may be reacted with the quartz in the bath 110, but not reacted with the Teflon layer. Thus, the KOH solution may isotropically etch the inner wall of the bath 110 to form the grooves 116 at the inner wall of the bath 110. Because the inner wall of the bath 110 may be isotropically etched, each of the grooves 116 may have an inlet diameter and a bottom diameter longer than the inlet diameter.

The reaction preventing layer 120 may be formed on the inner wall of the bath 110 to fill up the grooves 116. The reaction preventing layer 120 may not be reacted with the phosphoric acid solution S. Therefore, the reaction preventing layer 120 may reduce or prevent the likelihood of a contact between the phosphoric acid solution S and the bath 110 such that the phosphoric acid solution S and the bath 110 may not be chemically reacted with each other. Further, portions of the reaction preventing layer 120 in the grooves 116 may secure the reaction preventing layer 120 to the bath 110 such that the reaction preventing layer 120 may not be detached from the bath 110.

The reaction preventing layer 120 may be formed on the entire inner face of the bath 110. The grooves 116 may be formed at the entire inner face of the bath 110. Thus, the reaction preventing layer 120 may reduce or prevent the likelihood of a contact between the phosphoric vapor from the phosphoric acid solution S and the phosphoric vapor from the bath 110.

In example embodiments, the reaction preventing layer 120 may be formed on the inner wall of the bath 110 having the grooves 116. Alternatively, the reaction preventing layer 120 may be formed on a coarsely grinded inner wall of the bath 110. The coarsely grinded inner wall of the bath 110 may be obtained by a sand blast process.

The supply member 130 may include a supply line 132 for transmitting the phosphoric acid solution S and nozzles 134 for injecting the phosphoric acid solution S into the bath 110. The supply line 132 may be arranged at the bottom face of the main chamber 112. Further, supply line 132 may extend to the outside of the bath 110. The nozzles 134 may be arranged at the same intervals on the supply line 132 along a lengthwise direction of the supply line 132. Thus, the supply member 130 may upwardly inject the phosphoric acid solution S from the bottom face of the main chamber 112.

The exhaust member 140 may be located at the bottom face of the auxiliary chamber 114. The phosphoric acid solution S may be exhausted through the exhaust line 140 from the bath 110.

The supply member 130 and the exhaust member 140 may include Teflon. Particularly, the supply member 130 and the exhaust member 140 may include per-fluoro-alkoxy (PFA) used at a higher temperature. Thus, the supply member 130 and the exhaust member 140 may not be reacted with the phosphoric acid solution S.

Additionally, the apparatus 100 may further include a pump (not shown), a filter (not shown), and a heater (not shown). The pump may push out the phosphoric acid solution S to supply the phosphoric acid, solution S through the supply member 130 and to exhaust the phosphoric acid solution S through the exhaust member 140. The filter may filtrate the exhausted phosphoric acid solution S. To supply the phosphoric acid solution having a temperature of about 160° C. to about 170° C. to the bath 110, the heater may heat the phosphoric acid solution S.

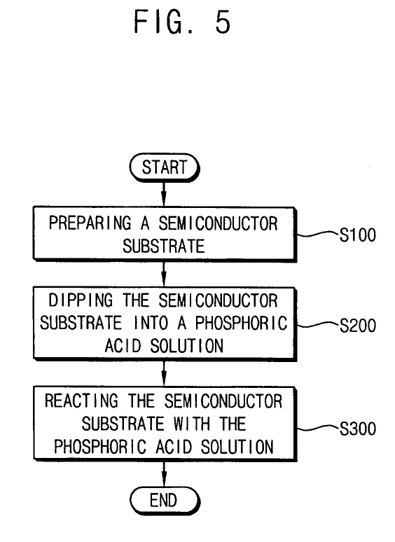

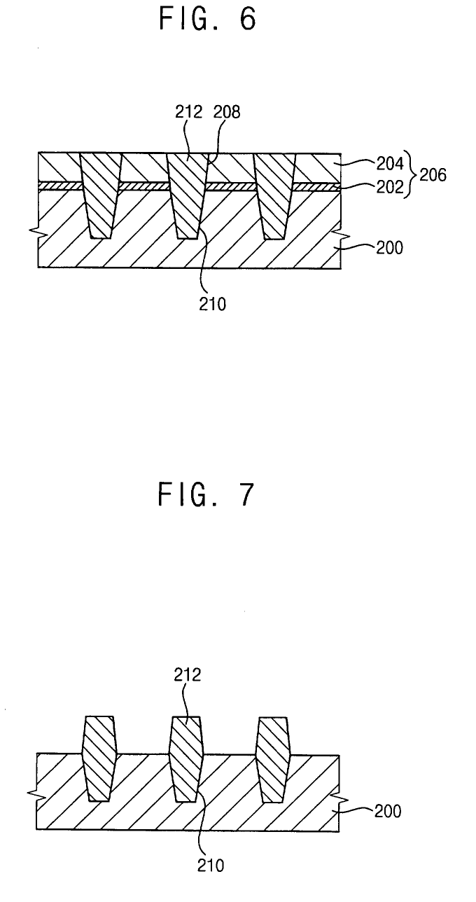

FIG. 5 is a flow chart illustrating a method of etching a semiconductor substrate in accordance with example embodiments. FIGS. 6 and 7 are cross-sectional views illustrating the method of FIG. 5.

Referring to FIGS. 5 and 6, in step S100, a semiconductor substrate 200 having trench structures 212 and an insulation layer pattern 206 between the trench structures 212 may be prepared. The trench structures 212 may be formed in trenches of the semiconductor substrate 200. The trench structures 212 may include silicon oxide and the insulation layer pattern 206 may include silicon nitride or silicon oxide.

The semiconductor substrate 200 having the trench structures 212 and the insulation layer pattern 206 may be prepared by the following processes. An insulation layer (not shown) having a multi-layered structure in which a silicon oxide layer and a silicon nitride layer are sequentially stacked may be formed on the semiconductor substrate 200. A photoresist pattern (not shown) may be formed on the insulation layer to partially expose the insulation layer. The insulation layer may be partially removed by an etching process using the photoresist pattern as an etching mask. A stripping process using oxygen plasma may then be performed to remove the photoresist pattern to form the insulation layer pattern 206 having an opening 208 that partially exposes the semiconductor substrate 200. The opening 208 may have an inlet and a bottom face narrower than the inlet. The opening 208 may have a negative slope.

The insulation layer pattern 206 may include a silicon oxide layer pattern 202 and a silicon nitride layer pattern 204. An etching process may be carried out using the insulation layer pattern 206 as an etching mask to remove the portions of the semiconductor substrate 200 exposed through the opening 208. As a result, the trench 210 may be formed at the surface portion of the semiconductor substrate 200. The trench 210 may then be filled with an insulation material. Particularly, the trench 210 and the opening 208 of the trench 210 may be filled with the insulation material. A planarization process (e.g., an etch-back process, a chemical mechanical polishing (CMP) process, or etc.) may be performed until the surface of the insulation layer pattern 206 is exposed to remove the insulation material from the insulation layer pattern 206, thereby completing the semiconductor substrate 200 that may include the trench structures 212 and the insulation layer pattern 206 between the trench structures 212. Because the opening 208 may have a negative slope, the trench structures 212 in the openings 208 also may have a negative slope.

In step S200, the semiconductor substrate 200 may then be loaded into the bath 110. The phosphoric acid solution S for etching the semiconductor substrate 200 may be received in the bath 110. The reaction preventing layer 120 may be formed on the inner wall of the bath 110.

The semiconductor substrates 200 may be transferred into the main chamber 112 of the etching apparatus 100 using a carrier for transferring the semiconductor substrate 200. The semiconductor substrates 200 may be dipped into the phosphoric acid solution S. The semiconductor substrates 200 may be horizontally arranged at the same intervals in the main chamber 112. The phosphoric acid solution S may have a temperature of about 160° C. to about 170° C., for example, about 165° C.

Referring to FIGS. 5 and 7, in step S300, the semiconductor substrate 200 may be chemically reacted with the phosphoric acid solution. The reaction preventing layer 120 may prevent a chemical reaction between the phosphoric acid solution S and the bath 110. The insulation layer pattern 206 and the trench structures 212 may be etched at a constant rate.

Because the reaction preventing layer may include Teflon on the inner wall of the bath 110, the phosphoric acid solution may not be reacted with the quartz in the bath 110. Thus, the etching rate of the phosphoric acid solution S with respect to silicon oxide may not be reduced. As a result, the life span of the phosphoric acid solution may be increased.

Therefore, when the semiconductor substrates 200 are dipped into the phosphoric acid solution S, the phosphoric acid solution S may be chemically reacted with the semiconductor substrate 200 to uniformly etch the insulation layer pattern including silicon nitride and silicon oxide, and the trench structures 212 including silicon oxide. Particularly, the phosphoric acid solution S may etch the silicon nitride layer pattern 204 of the insulation layer pattern 206 more than the silicon oxide layer 202 of the insulation layer pattern 206 and the trench structures 212 including silicon oxide. Further, the upper face and the side face of the trench structures 212 may be etched together with the silicon nitride layer pattern 204 while etching the semiconductor substrate 200. Therefore, a profile of the trench structures 212 protruding from the semiconductor substrate 200 may have a positive slope. As a result, when a polysilicon layer is formed between the trench structures 212 by the following process, a void may not form in the polysilicon layer.

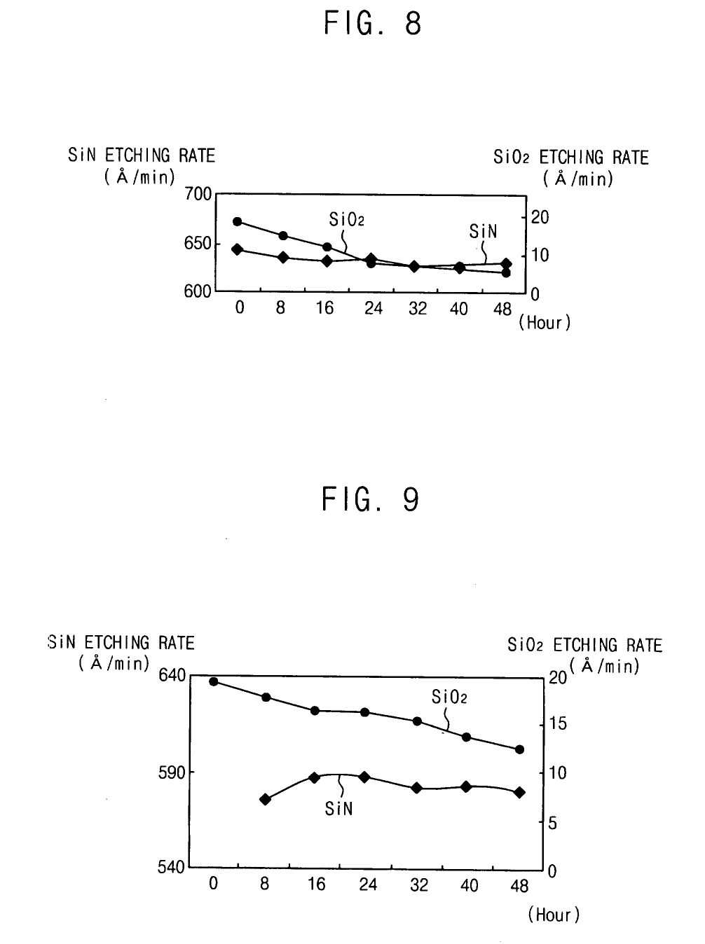

FIG. 8 is a graph illustrating etching rates of a phosphoric acid solution with respect to a silicon nitride layer and a silicon oxide layer as a function of the lapse of time when an etching process is performed on a semiconductor substrate.

Referring to FIG. 8, etching rates of the phosphoric acid solution with respect to a silicon nitride layer and a silicon oxide layer were measured every four hours while performing an etching process on a semiconductor substrate in a bath having quartz in which a phosphoric acid solution was received. The phosphoric acid solution with respect to the silicon nitride layer had a constant etching rate of about 650 Å/min regardless of the lapse of time. In contrast, the etching rate of the phosphoric acid solution with respect to the silicon oxide layer was decreased from about 18 Å/min to about 18 Å/min after 48 hours.

FIG. 9 is a graph illustrating etching rates of a phosphoric acid solution with respect to a silicon nitride layer and a silicon oxide layer as a function of the lapse of time when an etching process is not performed on a semiconductor substrate.

Referring to FIG. 9, etching rates of the phosphoric acid solution with respect to a silicon nitride layer and a silicon oxide layer were measured every four hours without performing an etching process on a semiconductor substrate in a bath having quartz in which a phosphoric acid solution was received. The phosphoric acid solution with respect to the silicon nitride layer had a constant etching rate of about 590 Å/min regardless of the lapse of time. In contrast, the etching rate of the phosphoric acid solution with respect to the silicon oxide layer was decreased from about 18 Å/min to about 13 Å/min after 48 hours.

As illustrated in FIG. 8, when the etching process is performed, the etching rate of the phosphoric acid solution with respect to the silicon oxide layer may be gradually decreased in proportional to the lapse of time. Further, as illustrated in FIG. 9, when the etching process is not performed, the etching rate of the phosphoric acid solution with respect to the silicon oxide layer may be gradually decreased in proportional to the lapse of time. Therefore, the bath having the quartz may affect the decrease of the etching rate of the phosphoric acid solution with respect to the silicon oxide layer. Particularly, as shown in FIG. 8, the etching rate of the phosphoric acid solution with respect to the silicon oxide layer may be decreased by about 18 Å/min within 48 hours. Further, as illustrated in FIG. 9, the etching rate of the phosphoric acid solution with respect to the silicon oxide layer may be decreased by about 5 Å/min within 48 hours. Thus, the influence of the bath including the quartz on the decrease of the etching rate of the phosphoric acid solution with respect to the silicon oxide layer may be about 50%.

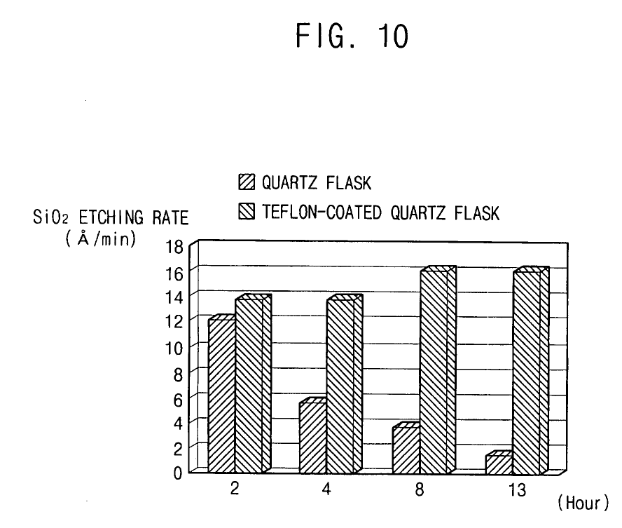

FIG. 10 is a graph illustrating the etching rate of a phosphoric acid solution with respect to a silicon oxide layer as a function of the lapse of time.

Referring to FIG. 10, phosphoric acid solutions were received in a quartz flask and a Teflon-coated quartz flask, respectively. Etching rates of the phosphoric acid solutions with respect to a silicon oxide layer were measured after 2 hours, 4 hours, 8 hours, and 13 hours. The etching rate of the phosphoric acid solution in the quartz flask with respect to the silicon oxide layer was gradually decreased. In contrast, the etching rate of the phosphoric acid solution in the Teflon-coated quartz flask with respect to the silicon oxide layer was constantly maintained. Therefore, the Teflon coating might reduce or prevent an occurrence of a chemical reaction between the phosphoric acid solution and the quartz flask so as to maintain the etching rate of the phosphoric acid solution with respect to the silicon oxide layer.

According to example embodiments, the silicon nitride layer and the silicon oxide layer on the semiconductor substrate may be etched using the phosphoric acid solution in the Teflon-coated quartz bath. Thus, the phosphoric acid solution may not be chemically reacted with the quartz bath so that the etching rate of the phosphoric acid solution with respect to the silicon oxide layer may not decrease. Further, because the etching rate of the phosphoric acid solution with respect to the silicon oxide layer may be reduced due to the chemical reaction between the phosphoric acid solution and the silicon oxide layer on the semiconductor substrate, the phosphoric acid solution may have a longer life span. Also, when the semiconductor substrate is etched using the phosphoric acid solution, the profile of the trench structure may have a positive slope.

The reaction preventing layer including quartz may be formed in the grooves of the bath such that the reaction preventing layer may not be detached from the bath. Therefore, the detached reaction preventing layer may not act as a particle.

The foregoing is illustrative of example embodiments and is not to be construed as limiting thereof. Although example embodiments have been described, those skilled in the art will readily appreciate that many modifications are possible in example embodiments without materially departing from the novel teachings and advantages of example embodiments. Accordingly, all such modifications are intended to be included within the scope of the claims. Therefore, it is to be understood that the foregoing is illustrative of example embodiments and is not to be construed as limited to the specific embodiments disclosed, and that modifications to the disclosed embodiments, as well as other embodiments, are intended to be included within the scope of the appended claims. Example embodiments are defined by the following claims, with equivalents of the claims to be included therein.

What is claimed is:

1. An apparatus for etching a semiconductor substrate, comprising:
a bath for receiving a chemical solution that is used for etching the semiconductor substrate, the bath having an inner wall at which a plurality of grooves is formed; and
a reaction preventing layer on the inner wall and in the grooves of the bath to reduce or prevent an occurrence of a chemical reaction between the chemical solution and the bath.

2. The apparatus of claim 1, wherein the bath comprises quartz and the reaction preventing layer comprises Teflon.

3. The apparatus of claim 1, wherein each of the grooves has an inlet diameter and a bottom diameter longer than the inlet diameter.

4. The apparatus of claim 1, further comprising:
a nozzle arranged at the bottom face of the bath to supply the chemical solution to the bath, the nozzle including quartz for reducing or preventing an occurrence of a chemical reaction between the nozzle and the chemical solution.

5. The apparatus of claim 1, wherein the chemical solution comprises a phosphoric acid solution having a temperature of about 160° C. to about 170° C.

6. A method of etching a semiconductor substrate, comprising:
preparing the semiconductor substrate including trench structures formed in trenches of the semiconductor substrate and an insulation layer pattern formed between the trench structures;
dipping the semiconductor substrate into a chemical solution of a bath that has an inner wall at which a plurality of grooves is formed, a reaction preventing layer being formed on the inner wall and in the grooves of the bath; and
reacting the semiconductor substrate with the chemical solution by blocking a chemical reaction between the chemical solution and the bath via the reaction preventing layer to etch the insulation layer pattern and the trench structures at a constant rate.

7. The method of claim 6, wherein the bath comprises quartz and the reaction preventing layer comprises Teflon.

8. The method of claim 6, wherein each of the grooves has an inlet diameter and a bottom diameter longer than the inlet diameter.

9. The method of claim 6, further comprising:
arranging a nozzle at the bottom face of the bath to supply the chemical solution to the bath, the nozzle including quartz for reducing or preventing an occurrence of a chemical reaction between the nozzle and the chemical solution.

10. The method of claim 6, wherein the chemical solution comprises a phosphoric acid solution having a temperature of about 160° C. to about 170° C.

11. The method of claim 6, wherein the trench structures comprise silicon oxide and the insulation layer pattern comprises silicon nitride.
